(19) United States
(12) Patent Application Publication
(10) Pub. No.: US 2004/0238846 A1
(43) Pub. Date: Dec. 2, 2004

(54) Organic electronic device

(76) Inventors: Georg Wittmann, Herzogenaurach (DE); Debora Henseler, Erlangen (DE); Karsten Heuser, Erlangen (DE); Ralph Paetzold, Roth (DE)

Correspondence Address: FISH & RICHARDSON P.C., 3300 DAIN RAUSCHER PLAZA, MINNEAPOLIS, MN, 55402, US

(21) Appl. No.: 10/794,700

(22) Filed: Mar. 4, 2004

Related U.S. Application Data
(60) Provisional application No. 60/475,078, filed on May 30, 2003.

(51) Int. Cl. H01L 31/109

(52) U.S. Cl. 257/200

(57) ABSTRACT

The invention discloses an organic electronic device including a substrate, an functional areahaving active elements and topographical steps, an active polymeric barrier layer on the functional area, which is able to bind the moisture and oxidizing agents and which planarizes the topographical steps of the functional area. A cap encapsulates the organic functional area and the active polymeric barrier layer.

Such an organic electronic device can easily be built with a thin-film encapsulation and also shows an enhanced shelf-life due to the enhanced barrier abilities of the cap and the active polymeric barrier layer.

This application claims the benefit of U.S. Provisional Application No. 60/475,078, filed on May 30, 2003, which is incorporated by reference herein.

### BACKGROUND

Many organic electronic devices, for example, organic light emitting devices (OLEDs), integrated plastic circuits or organic radiation sensors such as organic phototransistors, consist of components, which are often susceptible to oxidizing agents and moisture, resulting in a deterioration of the performance of the device when exposed to moisture or oxygen.

A conventional OLED device, for example, has a functional stack located on a substrate. The functional stack has one or more organic functional layers sandwiched between two conductive layers. The conductive layers function as electrodes (cathode and anode). When a voltage is applied to the electrodes, charge carriers are injected through these electrodes into the functional layers, and upon recombination of the charge carriers visible radiation can be emitted (electroluminescence). Most of the components of the functional stack, for example, the organic functional layer and the cathode layers, which normally comprise base metals like calcium or magnesium are very sensitive to moisture or oxidizing agents such as oxygen. The organic functional stack on the substrate is normally encapsulated by a cap, which can be, for example, glass or ceramic.

FIG. 1 shows a cross-sectional view of a conventional organic electroluminescent device with a patterned getter layer and encapsulated by a cover as described, for example, in the U.S. patent application publication US 2003/0038590 A1. A functional stack 5, which includes organic functional layers sandwiched between two electrically conductive layers, is located on a substrate 1 and is encapsulated by a cap 10 and a sealing region 20. A patterned getter layer 15 consisting of group IIA metals or group IIA metal oxides, such as calcium, barium, barium oxide or calcium oxide, laterally surrounds the functional stack 5 in the form of a ring and is located within the encapsulated area. The getter layer can absorb permeants. A gap d between the cap and the getter layer allows oxygen and moisture to permeate through the sealing region 20 as indicated by the arrows 12, without being absorbed by the getter layer. One disadvantage of this conventional device is that typically the cathode layer, which often is the top electrode layer, is not covered by the getter material. Therefore the cathode layer is exposed to moisture or oxygen permeating into the interior of the device.

Caps in the form of thin film encapsulations are under investigation for organic electronic devices. The organic electronic devices often have active areas comprising active elements with different topographical steps. OLEDs, for example, include topographical steps formed by bars with overhanging sections for structuring the functional layers and/or structuring the cathode layers, where the bars protrude from the active area. These topographical steps create a highly irregular surface on which thin film encapsulations are difficult to deposit.

### SUMMARY

There is a need for organic electronic devices with a reliable encapsulation that prevents the diffusion of moisture or oxidizing agents into the active organic area. Furthermore there is a need for organic electronic devices that have functional areas made in such a way that caps in the form of thin-film encapsulations can easily be generated on top of the functional area.

In general, in one implementation, techniques are provided for forming organic electronic devices that have components that are sensitive to moisture. The device includes a substrate and a functional area on the substrate that has organic active elements and topographical steps. An active polymeric barrier layer that binds moisture and oxidizing agents and forms a planar surface over the topographical steps is on the function area. A cap encapsulates the functional area and the active polymeric barrier layer.

### DESCRIPTION OF THE DRAWINGS

FIG. 1 shows a conventional electronic device.

FIG. 2 shows an organic electronic device constructed according to the invention.

FIG. 3 shows another embodiment of the organic electronic device constructed according to the invention.

FIG. 4 shows another variant of an organic electronic device constructed according to the invention.

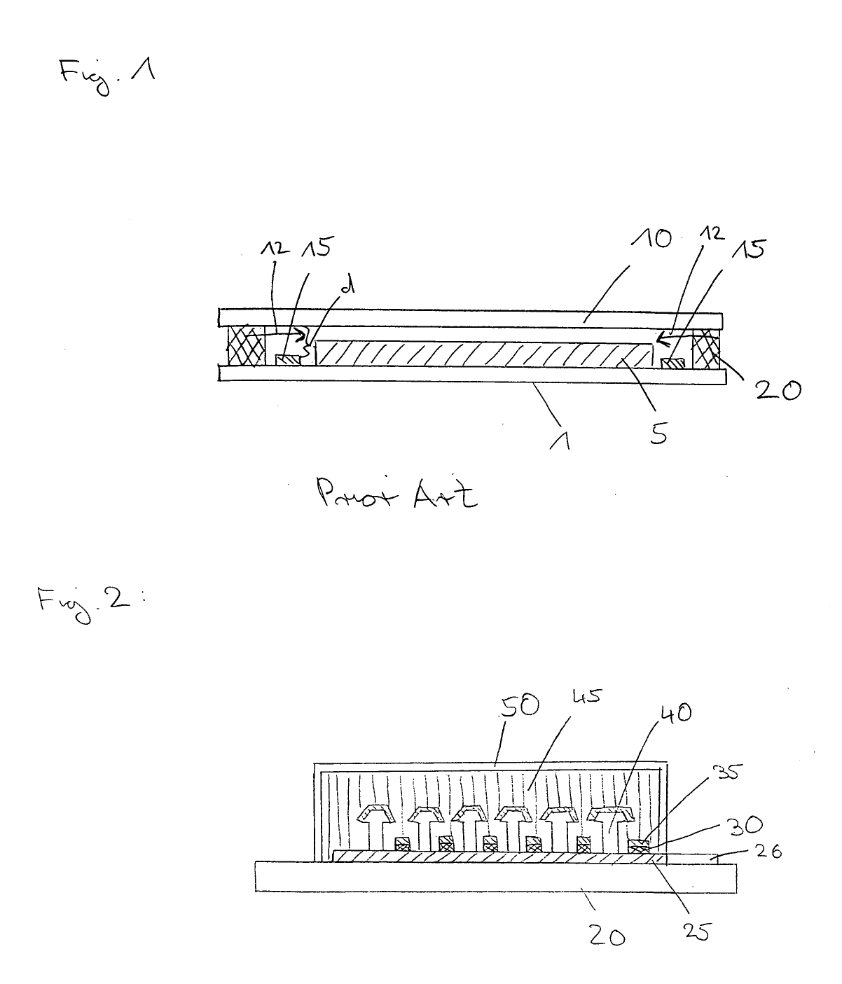

In the following the invention will be explained in more detail by the figures. All figures are simplified schematic representations presented for illustration purposes only.

### DETAILED DESCRIPTION

Organic electronic devices with active organic areas will have a longer lifespan when a reliable encapsulation prevents moisture or oxidizing agents from reaching the active organic area. Techniques are provided for forming organic electronic devices that have components that are sensitive to moisture. The device includes a functional area on a substrate, where the function area has organic active elements and topographical steps. An active polymeric barrier layer is on the fiction area. The active polymeric barrier layer binds moisture and oxidizing agents and forms a planar surface over the topographical steps. A cap encapsulates the functional area and the active polymeric barrier layer.

In contrast to conventional organic electronic devices, which use inorganic getter materials, the organic electronic device described herein provides an active polymeric barrier layer which can actively bind and therefore neutralize permeants such as moisture and oxidizing agents. This binding can take place by, e.g., chemi- or physisorption of the permeants.

Due to its polymeric nature, the active polymeric barrier layer can be much easier to process than the conventional inorganic getter materials and can, for example, be deposited over the top electrode of the functional stack of the organic electronic device as a liquid or paste, thereby planarizing the topographical steps normally present in the functional area.

The topographical steps are normally attributed to the different elements of the functional area. Elements of the functional area in the case of an OLED device can be bars with overhanging sections for separation of cathode stripes or layers with hollows defining the active pixel areas of the OLED device. OLED devices having bars with overhanging sections and layers with hollows for the definition of the active pixels are described in the pending German patent application, publication number DE 10133686 A1, which is herein incorporated in its entirety.

The topographical steps, e.g., the bars, can have a height of around 3 μm. It is possible to cover and planarize the topographical steps of the functional area with an active polymeric barrier layer with a thickness measured adjacent to the topographical steps greater than the height of the topographical steps, e.g., generally more than about 3 microns. The planarizing active polymeric barrier layer then provides a flat surface for the generation of a thin film encapsulation.

The active polymeric barrier layer can be selected from a polymeric matrix with dispersed cyclodextrines, cyclic olefin copolymers, a polymeric matrix with anhydrides and mixtures thereof.

Cyclodextrines are cyclic oligomers of α-D-glucose formed by the action of certain enzymes, such as cyclodextrin glucotransferases. The cyclodextrines can consist of six, seven or eight α-1,4-linked glucose monomers and are known as α-, β- or γ-cyclodextrines. The cyclodextrine molecules are orientated in a special manner relative to each other so that continuous channels are formed within the crystal lattice of the cyclodextrines. These channels have large hollow interiors of a specific volume and are therefore able to bind permeants, e.g., gas molecules. The permeants can even be linked covalently to the cyclodextrine molecules, for example, by the primary hydroxyl groups at the six-carbon positions of the glucose moiety and the secondary hydroxyl group in the two- and three-carbon positions of the molecule. These hydroxyl groups can also be replaced by other groups in order to change the solubility, compatibility and the thermostability of the cyclodextrines. The substitution of the hydroxyl groups can also be used to adjust the binding strength to a value between the binding strength of cyclodextrines and of potential permeants. Therefore the cyclodextrines should be able to permanently neutralize, for example, moisture or oxidizing agents. Cyclodextrines can be dispersed in a polymeric matrix like polypropylene.

The cyclic olefin copolymers can, for example, comprise two components which are blended by extrusion. One component can, for example, be an oxidizable polymer, such as poly(ethylene/methylacrylate/cyclohexenyl-methylacrylate) (EMCM). Another component can, for example, consist of a photoinitiator and a catalyst, for example, of a transition metal catalyst. Both components can form a so-called oxygen scavenging system which can be activated, for example upon exposure to UV-radiation. The cyclic olefin groups of these polymers are then able to chemically react, e.g., with oxygen molecules via ring opening reactions or aromatization reactions.

In another embodiment, the active polymeric barrier layer can be a polymeric matrix with anhydrides. The anhydrides can be carbonic acid anhydrides which can be formed by removing water from the respective free acids. Therefore, these anhydrides should be able to bind moisture, e.g., water molecules, very effectively. Examples for acid anhydrides are acid anhydrides of organic acids like maleic anhydride. The acid anhydrides can bind covalently to the polymeric matrix, e.g., polystyrene. It is also possible to use a mixture of cyclodextrines, cyclic olefin copolymers and anhydrides to ensure an optimal barrier performance for different types of oxidizing agents or moisture.

It is also possible to use liquid crystal polymers as an active polymeric barrier layer. These polymers exhibit the same properties as liquid crystals and are often synthesized by the polycondensation of aromatic dicarboxylic acids and aromatic diamines or phenols.

The active polymeric barrier layer is able to bind the moisture and oxidizing agents chemically and permanently. Chemical binding ensures an optimal absorption and neutralization of the moisture and oxidizing agents.

The medium thickness of the active polymeric barrier layer is around 1 to 10 μm. This thickness is enough to cover and therefore planarize most of the topographical steps in functional areas which are attributed to the different elements of the functional area.

The substrate of the organic electronic device of the invention is selected from glass, metal, polymer and ceramic. Glass substrates can be used in so-called bottom-emitting OLED devices, where the light generated by the organic functional stack is emitted through the substrate.

A cap encapsulating the organic functional stack can be formed of, for example, a material such as polymer, metal, ceramic and glass, or combinations thereof. The cap can also include barrier assemblies of active polymeric barrier layers and ceramic barrier layers.

In another embodiment of the organic electronic device of the invention the cap provides a cavity between the cap and the functional area. In this case the active polymeric barrier layer can maintain a thickness sufficient to prevent the cap from contacting the functional area. The active polymeric barrier layer is located between the cap and the functional area and can provide a barrier that can hold back the cap and therefore prevent damage to the functional area. The active polymeric barrier layer can essentially fill the cavity. The cap, for example a transparent glass cap, can be mounted on the active polymeric barrier layer and can be supported by the active polymeric barrier layer. Such an arrangement also provides a more stable cap.

The cap can also comprise a ceramic barrier layer which is located on the active polymeric barrier layer that planarizes the topographical steps of the functional area. Such a ceramic barrier layer can physically prevent the moisture and oxidizing agents from permeating from the outside environment into the interior of the organic electronic device. In this embodiment, residual moisture and oxidizing agents permeating through the defects of the ceramic barrier layer can be absorbed and neutralized by the active polymeric material of the underlying active polymeric barrier layer. The ceramic barrier layer normally has a thickness of between about 1 and 250 nanometers. Therefore, it is possible to build up thin-film encapsulations on organic electronic devices of the invention by generating a ceramic barrier layer on the active polymeric barrier layer. It can take approximately 10,000 hours before the first permeating molecule can reach the organic active area encapsulated by a thin-film encapsulation having a ceramic barrier layer with a diffusion rate of 10⁻³ g/(m²/day) arranged on a 1 μm thick active polymeric barrier layer.

In one embodiment, the ceramic barrier layer can be selected from metal nitrides, metal oxides and metal oxynitrides. The metal components of these metal nitrides, metal oxides or metal oxynitrides can be aluminum. Alternatively, the ceramic barrier layer can be selected from silicon nitride, silicon oxide and silicon oxynitride. These ceramic barrier layers can provide a very good physical barrier for the permeation of gases or liquids. Apart from these materials other ceramic materials, that comprise predominantly inorganic and non-metallic compounds or elements can be used.

In another embodiment, the substrate or the cap and the active polymeric barrier layer are transparent. In the case of organo-optical devices where the substrate is transparent; for example glass, so-called bottom-emitting OLEDs can be built where the generated light can emit through the substrate. Where the cap and the active polymeric barrier layer are transparent, so-called top-emitting OLEDs or TOLEDs can be built, where the light emitted by the functional area can pass through the cap and the polymeric barrier layer.

According to another embodiment of the invention, the cap comprises not just one ceramic barrier layer, but an assembly of alternating polymeric barrier layers and ceramic barrier layers. Such an assembly exhibits very high barrier abilities and, for example, shows permeation rates for moisture and oxygen of less than 10⁻⁶ g/(m²/day).

In another embodiment, the organic electronic device of the invention further comprises an additional barrier stack with at least one additional active polymeric barrier layer that is able to bind moisture and oxidizing agents and at least one ceramic barrier layer. Such a barrier stack, for example, is very useful for flexible organic electronic devices on flexible polymeric substrates. These flexible polymeric substrates normally exhibit very high permeation rates for water vapor and for oxidizing agents in the range of more than 1 g/(m²/day). In this case, the barrier stack can provide an additional barrier against the moisture and oxidizing agents, especially when it is arranged between the substrate and the functional area in order to absorb most of the moisture and oxygen permeating through the flexible substrate.

When an additional barrier stack is arranged between the substrate and the functional area, the functional area can be located on the barrier stack. The at least one additional active polymeric barrier layer of the barrier stack is located adjacent to the functional area, planarizing the unevenness of the ceramic barrier layer of the barrier stack. Normally the ceramic barrier layers exhibit an unevenness of around <25 nm rms, which can damage the sensitive components of the functional area.

In the case of a flexible substrate, the substrate can comprise a polymer, for example polyethersulfone (PES) or poly-ethylenetherephthalate (PET). In another variation of the invention the substrate itself is an active polymeric barrier layer. Normally the polymeric substrates of flexible organic electronic devices are much thicker than the ceramic barrier layers or the active polymeric barrier layers. Flexible polymeric substrates normally have a thickness of around 100 to 200 μm. The polymeric substrate can be formed by coextruding the materials that scavenge moisture and oxidizing agents, such as cyclodextrines, the cyclic olefine copolymers or the anhydrides. The polymeric substrate itself can function as an active polymeric barrier layer. Such a substrate can exhibit very high barrier abilities due to its thickness.

When a substrate functions as an active polymeric barrier layer, a ceramic barrier layer can be arranged on the substrate, protecting the substrate from the environment outside the device. Such a ceramic barrier layer can prevent most of the moisture and oxidizing agents from contacting the active polymeric barrier.

The functional area can include a stack of a first electrically conductive layer, an organic functional layer on the first conductive layer, and a second electrically conductive layer on the functional layer. The organic functional layer can include at least one organic electroluminescent layer. An electronic device with such an organic functional stack forms an organic electroluminescent device.

The organic functional layer between the first electrically conductive and the second electrically conductive layer can also be an organic, radiation-detecting layer, so that the electronic device provides an organic radiation-detecting device, for example an organic solar cell. The organic functional stack can also form a so-called integrated plastic circuit comprising an organic electrically conductive material.

FIG. 2 depicts a cross-sectional view of an organic electronic device of the invention, an OLED device. A first electrically conductive layer 25 in the form of parallel stripes is located on a substrate 20. Bars 40 with overhanging sections are arranged on the first electrically conductive layer 25. Organic fictional layers 30 are deposited in the gaps between two adjacent bars 40 on the first conductive layer 25. A second electrically conductive layer 35 which is structured by the bars 40 in the form of stripes running perpendicular to the stripes of the first electrically conductive layer 25 can be formed by depositing a continuous film of electrically conductive material over the entire area of the functional area. The continuous film breaks up at the overhanging sections of the bars forming stripes 35. The arrangement of organic functional stacks comprising the electrically conductive layers 25, 35 and the organic functional layers 30 in conjunction with the bars 40 result in different topographical steps in the functional area. These topographical steps are covered and planarized by an active polymeric barrier layer 45 which is deposited over the entire arrangement of elements of the functional area. A cap 50, for example glass, encapsulates the whole functional area and the active polymeric barrier layer 45. The active polymeric barrier layer 45 also can support the cap 50, preventing contacts between the cap and the organic functional stack. Contact pads 26 can be present in order to electrically contact the first conductive layer 25 from outside of the device.

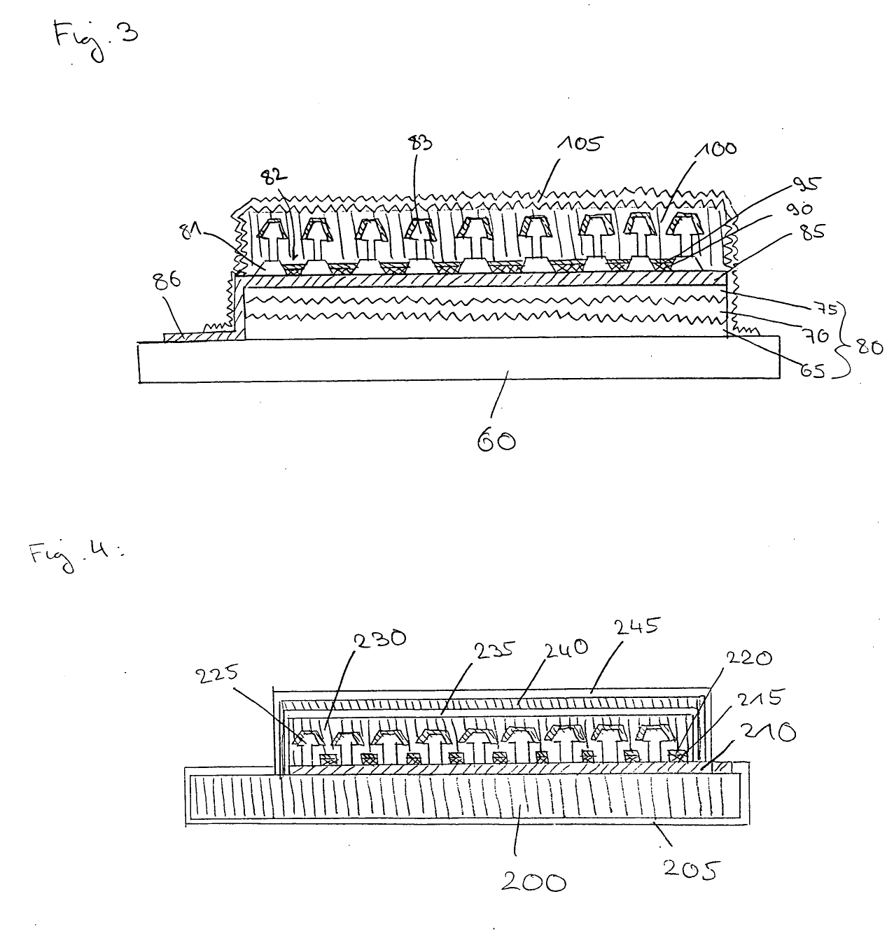

FIG. 3 shows another embodiment of a flexible organic OLED device. A barrier stack 80 consisting of two active polymeric barrier layers 65 and 75 and one ceramic barrier layer 70 is located on a flexible polymeric substrate 60. An functional area having two electrically conductive layers 85 and 95 in the form of stripes running perpendicular to each other and one organic functional layer 90 is located on top of the barrier stack 80. The functional area also comprises a layer 81 with hollows 82 defining the active pixels of the OLED device. Additionally bars 83 with overhanging portions for the separation of the cathode stripes are located on top of the hollow layer 81. This complete arrangement of the organic functional stack, the hollow layer 81 and the bars 83, is covered and planarized by an active polymeric barrier layer 100. In this embodiment, the cap 105 consists of a ceramic barrier layer. Both ceramic barrier layers 105 and 70 have an unevenness, which is schematically indicated by the jagged lines of the ceramic layers. Active polymeric barrier layers 100 or 75 are located between the respective ceramic barrier layers and the organic active area in order to additionally planarize the unevenness of both ceramic barrier layers preventing any damage to the functional area. Contact pads 86 enable an external electrical contact to the first electrically conductive layer 85.

FIG. 4 depicts a cross-sectional view of another embodiment of an OLED device. An functional area including a first electrically conductive layer 210, an organic functional layer 215 and a second electrically conductive layer 220 together with bars 225 is located on a flexible substrate 200 which is an active polymeric barrier layer. This active polymeric barrier layer substrate is protected from the outside environment by a ceramic barrier layer 205 located on the surface of the substrate. The topographical steps of the functional area are planarized by an active polymeric barrier layer 230. On top of this active polymeric barrier layer 230 is an assembly of a ceramic barrier layer 235, an active polymeric barrier 240 and another ceramic barrier layer 245.

The scope of the invention is not limited to the embodiments shown in the figures. Indeed, variations especially concerning the sequence of ceramic barrier layers and active polymeric barrier layers in the barrier stacks are possible. Moreover, other topographical steps except for the elements shown in the figures can be planarized by the active polymeric barrier layers of the device of the invention.

The invention is embodied in each novel characteristic and each combination of characteristics which includes every combination of any features which are stated in the claims, even if this combination of features is not explicitly stated in the claims.

We claim:

1. An organic electronic device, having components that are sensitive to moisture or oxidizing agents, comprising:
a substrate;
a functional area on the substrate, comprising organic active elements and having topographical steps;
an active polymeric barrier layer on the functional area, wherein the active polymeric barrier layer binds moisture and oxidizing agents and forms a planar surface over the topographical steps of the functional area; and
a cap encapsulating the functional area and the active polymeric barrier layer.

2. The device according to claim 1, wherein:
the active polymeric barrier layer includes one or more materials from the group consisting of a polymeric matrix with dispersed cyclodextrines, cyclic olefin copolymers and a polymeric matrix with anhydrides.

3. The device according to claim 1, wherein:
in areas between the topographic steps, the active polymeric barrier layer is thicker than the height of the topographical steps of the functional area, such that the active polymeric layer extends above the topographic steps.

4. The device according to claim 1, wherein:
the active polymeric barrier layer is between about 1 and 10 μm thick.

5. The device according to claim 1, wherein:
the active polymeric barrier layer binds the moisture and oxidizing agents chemically.

6. The device according to claim 1, wherein:
the substrate includes one or more materials from the group consisting of glass, metal, polymer and ceramic.

7. The device according to claim 1, wherein:
the cap includes one or more materials from the group consisting of polymer, metal, ceramic and glass.

8. The device according to claim 1, wherein:
the cap has a recess that provides a cavity between the cap and the functional area; and
the active polymeric barrier layer has a thickness sufficient to prevent the cap from contacting the functional area.

9. The device according to claim 8, wherein:
the active polymeric barrier layer substantially fills the cavity.

10. The device according to claim 1, wherein:
the cap comprises a ceramic barrier layer.

11. The device according to claim 10, wherein:
the ceramic barrier layer includes one or more materials selected from the group consisting of a metal nitride, a metal oxide,and a metal oxynitride.

12. The device according to claim 11, wherein:
the metal is aluminum.

13. The device according to claim 10, wherein:
the ceramic barrier layer includes a material selected from the group consisting of silicon nitride, silicon oxide, silicon oxynitride and combinations thereof.

14. The device according to claim 10, wherein:
the cap comprises an assembly of a plurality of polymeric barrier layers and the ceramic barrier layer is between a first polymeric barrier layer and a second polymeric barrier layer of the plurality of ceramic barrier layers.

15. The device according to claim 1, further comprising:
a barrier stack having at least one active polymeric barrier layer that binds the moisture and oxidizing agents and at least one ceramic barrier layer.

16. The device according to claim 15, wherein:
the barrier stack is arranged between the substrate and the functional area.

17. The device according to claim 16, wherein:
the functional area is located on the barrier stack; and
the at least one active polymeric barrier layer of the barrier stack is adjacent to the functional area, and forms a planar surface over the ceramic barrier layer of the barrier stack.

18. The device according to claim 17, wherein:
the substrate is flexible and comprises a polymer.

19. The device according to 17, wherein:
the substrate is an active polymeric barrier layer.

20. The device according to claim 19, wherein:
a ceramic barrier layer is arranged on the substrate such that the ceramic barrier layer protects the substrate from an environment outside the device.

21. The device according to claim 1, wherein:
the functional area is a stack of layers comprising a first electrically conductive layer, an organic functional layer on the first conductive layer and a second electrically conductive layer on the organic functional layer; and
the functional area comprises at least one organic electroluminescent layer forming an OLED.

22. The device according to claim 1, wherein:
the functional area is a stack of layers comprising a first electrically conductive layer, an organic functional layer on the first conductive layer and a second electrically conductive layer on the organic functional layer; and
the functional area comprises at least one organic radiation-detecting layer forming an organic radiation sensor.

23. The device according to claim 1, wherein:
the functional area comprises an integrated plastic circuit.

24. The device according to claim 1, wherein:
at least one of the substrate, the cap and the active polymeric barrier layer are transparent.
